(19) United States
(12) Patent Application Publication
(10) Pub. No.: US 2021/0028480 A1
(43) Pub. Date: Jan. 28, 2021

(54) ASSEMBLY MOULD TO MANUFACTURE A THREE-DIMENSIONAL DEVICE COMPRISING SEVERAL MICROELECTRONIC COMPONENTS

(71) Applicant: COMMISSARIAT A L'ENERGIE ATOMIQUE ET AUX ENERGIES ALTERNATIVES, Paris (FR)

(72) Inventors: Messaoud BEDJAOUI, Grenoble Cedex 09 (FR); Jean BRUN, Grenoble Cedex 09 (FR); Sylvain POULET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 16/930,358

(22) Filed: Jul. 16, 2020

(30) Foreign Application Priority Data
Jul. 24, 2019 (FR) 19 08400

(51) Int. Cl. H01M 10/04

(52) U.S. Cl. CPC H01M 10/0404; H01M 2220/30; H01M 10/0436

(57) ABSTRACT

A reusable assembly mould, to manufacture a three-dimensional device comprising several microelectronic components vertically stacked, comprising a main cavity, formed by a bottom and a side wall, and configured to receive at least two stacked elementary structures, each elementary structure comprising a brittle substrate covered with a microelectronic component and with electrical contacts, disposed on the edge of the substrate, the assembly mould being of a deformable material able to undergo a non-permanent deformation from 10 to 1000% relative to its initial shape, preferentially from 50 to 200% relative to its initial shape,
the assembly mould further comprising a clearance positioned along the side wall of the main cavity to facilitate handling of the first elementary structure and/or of the second elementary structure and/or to inject an element along the main cavity.

### TECHNICAL FIELD

The present invention generally relates to the field of vertical assembly, encapsulation and electrical interconnection for microelectronic components and more particularly lithium microbatteries.

The invention relates to a mould to manufacture a three-dimensional device comprising several microelectronic components vertically stacked.

The invention also relates to a method for manufacturing such a three-dimensional device.

The invention is particularly interesting since it provides a method for vertically and accurately assembling several microelectronic components, disposed on ultrathin substrates. In addition to good electrochemical performance of assemblies made, a complete encapsulation of microelectronic components is obtained while offering easy electrical interconnection of these electrical components. Moreover, the invention is compatible with integrating steps with external microelectronic circuits.

The invention is applicable in numerous industrial fields, and especially in the field of energy and multifunction self-contained systems.

### State of Prior Art

In recent years, connected objects (or IoT for “Internet of Things”) have been booming. These objects sometimes need to be associated with microelectronic devices for energy recovery and storage. Such devices have to meet numerous technological requirements, in order to be able to be used with these connected objects, such as good electric performance, highly conformable dimensions and a reduced overall size. Especially, in the case of microbatteries, it is necessary to have microbatteries having good electrochemical performance and very large volume capacities, that is a high ratio of the surface capacity to the volume of the component.

To optimise electrochemical performance of microbatteries, they are several levers: the shape and dimensions (“design”) of active layers, nature of electrode materials used, manufacturing methods and packaging techniques.

Optimising the volume capacity of microbatteries can be achieved by reducing the overall size of so-called passive layers, especially the overall size of the encapsulation layer and interconnection layers, relative to the so-called active layers, such as electrodes.

One of the solutions of the state of the art consists in stacking several unit components in order to favourably meet these problems, such as described in documents US 2017/0111994 A1 and US 2009/0136839 A1. Electrical interconnection between unit microbatteries is obtained by filling, with conductive adhesives, through vias formed at each corner of the host substrate. The main drawback of these solutions lies in creating brittle zones at the end of the components (corners). This drawback is highly marked for so-called ultrathin substrates (having a thickness lower than 100 μm, or even lower than 50 μm) having a surface area the dimensions of which are down to the millimetre.

### DISCLOSURE OF THE INVENTION

One purpose of the present invention is to provide a method for manufacturing a three-dimensional device comprising several microelectronic components vertically stacked, having a strong volume capacity and a good mechanical strength, even for ultrathin substrates, for easily and accurately stacking microelectronic components and easily performing electric interconnection of these components.

To do so, the present invention provides a reusable assembly mould, to manufacture a three-dimensional device comprising several microelectronic components vertically stacked, comprising a main cavity, formed by a bottom and a side wall, and configured to receive at least two stacked elementary structures (i.e. at least a first elementary structure and a second elementary structure which are stacked), each elementary structure comprising a brittle substrate covered with a microelectronic component and with electrical contacts, disposed on the edge of the substrate, the assembly mould being of a deformable material able to undergo a non-permanent deformation from 10 to 1000% relative to its initial shape, preferentially from 50 to 200% relative to its initial shape.

The assembly mould further comprises a clearance positioned along the side wall to facilitate handling of the first elementary structure and/or of the second elementary structure and/or to inject an element along the cavity. This is particularly advantageous to form electrical contacts along the elementary structures.

By brittle, it is meant a thin or ultrathin substrate, i.e. having a thickness lower than 100 μm and preferentially lower than 50 μm.

The assembly mould is a compartmentalised support. The main cavity of the mould is used to position and frame the elementary structures to be stacked. The bottom of the mould has the same shape and same dimensions as the substrate of the elementary structures so as to be able to accurately stack the elementary structures and vertically align their electrical contacts.

With such a mould, microelectronic components are easily stacked onto each other without having to resort to positioning and aligning techniques of the state of the art.

The elementary structures disposed into the main cavity of the mould can be easily electrically connected in parallel or in series, on the edges of the substrate, without having to form vias in the substrates of the elementary structures. More than two elementary structures (for example from 4 to 7 elementary structures) can be positioned into the main cavity.

The mould is a stretchable material, able to be deformed, which facilitates positioning the elementary structures and/or removing the final assembly. It is reusable.

Advantageously, the mould is a polymeric material, preferably, polysiloxane. Such moulds are simple, quick and inexpensive to manufacture. Polydimethylsiloxane (PDMS) will be preferably chosen. After curing, flexibility and mobility of the polymer chain of the PDMS material result in an excellent elasticity and good tearing strength allowing multiple compression and extension movements. PDMS assembly moulds can have a deformability with an elongation of 120% and a tensile strength in the order of 7.1 MPa. Making use of this elasticity property facilitates the mould release step.

Advantageously, the bottom of the main cavity has a square shape.

Advantageously, the assembly mould comprises an additional cavity, in fluid connection with the main cavity, forming a tank, especially for injecting an electrically insulating adhesive.

The invention also relates to a method for manufacturing a three-dimensional device comprising several microelectronic components vertically stacked, the method comprising the following steps of:

a) providing a first elementary structure and a second elementary structure, each elementary structure comprising a substrate having a first main face and a second main face, the first main face of the substrate being covered with a microelectronic component, and with electrical contacts, disposed on the edge of the substrate, and electrically connected to the microelectronic component,

b) providing an assembly mould such as previously defined, comprising a main cavity, formed by a bottom and a side wall, and configured to receive at least two elementary structures, the assembly mould being made of a deformable material able to undergo a non-permanent deformation from 10 to 1000% relative to its initial shape, preferentially from 50 to 200% relative to its initial shape,

c) disposing the first elementary structure into the main cavity of the assembly mould,

d) forming an electrically insulating adhesive layer between the first elementary structure and the second elementary structure,

e) disposing the second elementary structure into the main cavity of the assembly mould,

f) electrically connecting the electrical contacts of the first elementary structure and the second elementary structure,

whereby a three-dimensional device is formed, having a good mechanical strength and the microelectronic components of which are electrically connected at the edges of the substrates of the elementary structures.

The method is fundamentally different from methods of prior art by implementing the assembly mould previously described. The advantages related to the assembly mould are the same for the method.

Advantageously, steps d), e) and f) are performed in the following order: e), d) and then f), or e), f) and then d). In particular, implementing steps e), f) and d) is interesting if there are two clearances along the cavity (one to form electrical contacts and one to inject the insulating adhesive).

Advantageously, the assembly mould comprises an additional cavity, in fluid connection with the main cavity, forming tanks, and the electrically insulating adhesive layer is formed by injecting the electrically insulating adhesive between the elementary structures from the additional cavity.

Mechanically securing elementary structures to each other is performed by means of the electrically insulating adhesive.

Advantageously, the assembly mould comprises at least one clearance, positioned along the side wall of the main cavity, at the electrical contacts of the elementary structures and step f) is performed by filling the clearance with an electrically conductive element whereby the electrical contacts of both elementary structures are electrically connected.

With such a method, there is no need to make vias in the substrates of the elementary structures. The electrical contacts of all the elementary structures are linked, for example, by techniques of dispensing electrically conductive adhesives. Electrical interconnection of the elementary structures is advantageously made, along the side wall of the substrates of the elementary structures, and not therethrough as in methods of prior art.

Performing steps of electrically interconnecting and mechanically securing in two distinct steps prevents problems of chemical incompatibility in the liquid state between adhesives, which can deteriorate electrical conduction properties of the conductive adhesives. Indeed, in the case of an electrically conductive adhesive containing metallic inclusions, these can be buried in a bigger electrically insulating matrix, which affects electric conduction properties obtained by percolating metallic inclusions.

Arranging compartments (clearance and tank) enables the flow and excess of adhesives used to be better channelled.

The assembly method is simple to implement. Microelectronic components, and especially lithiated layers of microbatteries, of the elementary structures are efficiently encapsulated by means of this integrating method.

Advantageously, the mould is of polysiloxane, and preferably of PDMS. These materials have aversion properties towards electrically insulating and conductive adhesives, due to the incompatibility of the chains of the polymer with hydrophilic surfaces or products. The final assembly is easy to remove from the assembly mould.

This method is easy to implement relative to the methods according to prior art which need relatively complex and/or expensive equipment for handling components to make vertical stacks.

The assembly mould necessary to implement the method according to the invention is an inexpensive element, easy to manufacture and to use.

A three-dimensional device, obtained by the previously described method, comprises a first elementary structure and a second elementary structure, forming a vertical stack, each elementary structure comprising a substrate covered with a microelectronic component and with electrical contacts electrically connected to the microelectronic component, a layer of electrically insulating adhesive being disposed between the first elementary structure and the second elementary structure, and an electrically conductive layer electrically connecting the electrical contacts of the first elementary structure and the second elementary structure, along the vertical stack.

Such a device can comprise from 4 to 7 vertically stacked elementary structures.

The device obtained has a good mechanical strength.

In the device, electric interconnection between the different stages is ensured by the continuity of conductive adhesive dots between the different levels of electrical contacts of each elementary structure. For this reason, electric connections are located on the flanks of the assembled module and not through the substrates. Recontacting can then be made on the flanks of the module or on the surface of the first or last component making up the stack.

In this device, the overall size of so-called passive layers, especially the encapsulation layer and the interconnection layers is reduced: the volume capacity (defined by the ratio of the surface capacity to the volume of the microelectronic component) is improved.

By means of miniaturisation and compactness of the device containing the microelectronic components, this device is particularly interesting for applications in the field of energy recovery. The device can comprise several identical or different microelectronic components, for example microbatteries interconnected with other microelectronic devices (such as electrochrome systems or photovoltaic cells), to make multifunctional self-contained systems.

Further characteristics and advantages of the invention will become apparent from the following additional description.

Of course, this additional description is only given by way of illustrating purposes of the object of the invention and should in no way be construed as a limitation of this object.

### BRIEF DESCRIPTION OF THE DRAWINGS

The present invention will be better understood upon reading the description of examples of implementation given by way of purely indicating and in no way limiting purposes with reference to the accompanying drawings in which:

FIG. 1 schematically represents in a cross-section view a microbattery, according to a particular embodiment of the invention,

FIG. 2 schematically represents in a bottom view the front face of the substrate of a microbattery as well as anode and cathode contacts, according to a particular embodiment of the invention,

FIG. 3 schematically represents in a cross-section view a rigid microstructured support, according to a particular embodiment of the invention,

FIG. 4 schematically represents in a top view a rigid microstructured support, according to a particular embodiment of the invention,

FIG. 5 schematically represents in a top view an assembly mould, according to a particular embodiment of the invention,

FIG. 6 is a photograph picture of assembly mould of polymeric material, according to a particular embodiment of the invention,

FIGS. 7a, 7b, 8, 9, 10 and 11 schematically represent different steps of the method for manufacturing an assembly of vertically stacked microelectronic components, according to different embodiments of the invention,

FIG. 12 represents pictures made by tomography microscopy of a vertical assembly obtained according to a particular embodiment of the invention.

Different parts represented in the figures are not necessarily drawn to a uniform scale, in order to make figures more legible.

Different possibilities (alternatives and embodiments) have to be understood as not being exclusive of each other and can be combined to each other.

Furthermore, in the description below, terms depending on the orientation, such as “above”, “below”, etc. of a structure are applied considering that the structure is oriented in the illustrated way in the figures.

### DETAILED DISCLOSURE OF PARTICULAR EMBODIMENTS

In the following, even if the description refers to microbatteries, and more particularly lithium microbatteries, the method can be applied for encapsulating and vertically assembling other microelectronic components.

Although in no way limiting, the invention particularly finds application in the field of energy and for manufacturing multifunctional self-contained systems having a large volume capacity.

The method for manufacturing a three-dimensional device comprising a vertical stack of microbatteries comprises the following steps of:

manufacturing microbatteries 300,
manufacturing the assembly mould 500 from a rigid structured support 400,
positioning microbatteries 300 in the assembly mould 500,
forming recontacting elements 320,
encapsulating microbatteries and mechanically reinforcing the module of microbatteries with an electrically insulating layer 330,
separating the module of microbatteries from the assembly mould 500.

Step 1: Manufacturing Microbatteries 300 on a Substrate 200:

Substrate 200:

The substrate 200, also called a host substrate or support substrate is thin or ultra-thin, i.e. it has a thickness lower than 100 μm and preferentially lower than 50 μm. Such thicknesses are for meeting volume capacity increase requirements.

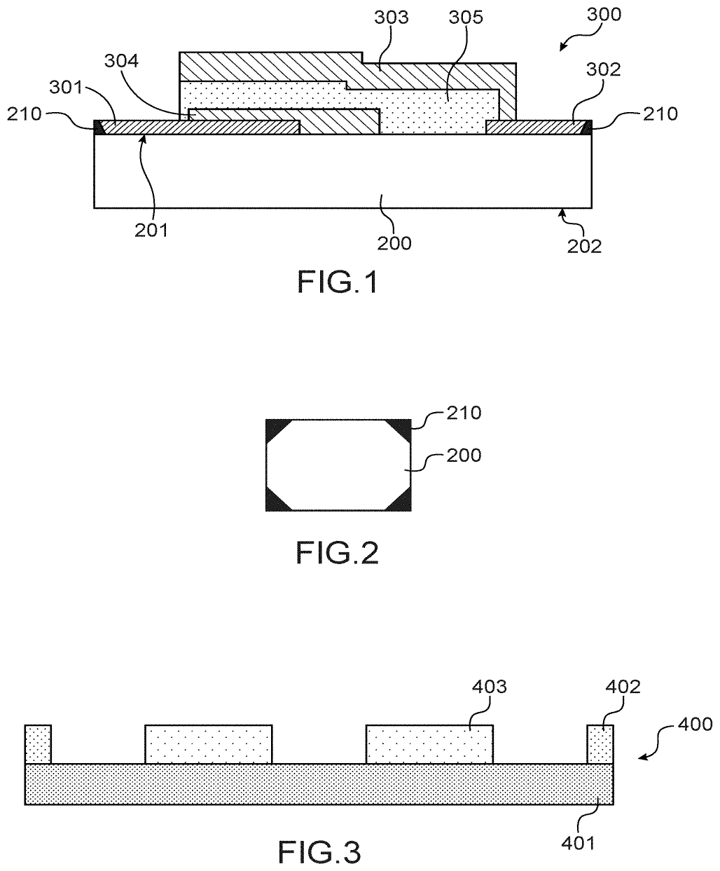

As represented in FIG. 1, the substrate 200 includes a first main face 201, called an active face (or front face), opposite to a second main face 202 (called a back face). The substrate 200 also comprises a side face from the first main face 201 to the second main face.

The substrate 200 can have different geometric shapes. It is for example possible to use wafer type circular forms or sheet forms, that is rectangular forms.

The substrate advantageously has performance required for encapsulating lithium microbatteries. It is made of a material having WVTR (Water Vapour Transmission Rate) and OTR (Oxygen Transmission Rate) barrier levels at most, respectively, of 10⁻⁴ g/m²/d and of 10⁻⁴ cm³/m²/d to ensure sufficient sealing properties towards air and water vapour.

The substrate 200 can be of a material selected from glasses, (single crystal or polycrystalline) silicon, ceramics, mica, and quartz.

Preferably, it is of glass. Such substrates are compatible with methods of thinning by grinding, despite the presence of a strong topography induced by stacking the active layers of microbatteries.

Glasses can be borosilicates (such as D263®LA, D263®M, D263®T, MEMpax® or Borofloat® marketed by SCHOTT® company), borosilicate derivatives such as alkali-free borosilicate glasses (AF32®, AF45, Corning® Willow . . . ) or boro-aluminosilicate glasses (alkaline earth boro-aluminosilcates) for example marketed by Corning Lotus™, EAGLE XG® companies. Such substrates are perfectly adapted to methods for manufacturing lithium microbatteries.

Preferably, the substrate 200 is transparent to laser wavelengths conventionally used for cutting steps. By transparent, it is meant that the substrate 200 allows at least 50% of light emitted by the laser to pass through.

Microelectronic Device 300:

At least one microelectronic device 300 is disposed on the first main face 201 of the substrate 200 (active face). The microelectronic device has a thickness ranging from 5 μm to 30 μm, and preferably from 10 to 15 μm.

For example, the outer dimensions of the microelectronic device are 4 mm×4 mm.

The first face 201 of the substrate 200 can include several microelectronic devices 300 in order, for example, to multiply electrochemical performance by a parallel or series connection of microelectronic devices. The microelectronic devices 300 can be identical or different.

By microelectronic device, it is meant a microelectronic component 300, such as for example, an MEMS (Micro-ElectroMechanical System), MOEMS (Micro-Opto-Electro-Mechanical System), infrared micro-sensor, transistor, microbattery, capacitor, supra-capacitor, photovoltaic component, antenna or any other device deemed to be necessary for making connecting objects.

In the following, even if the description refers to an elementary structure-microbattery, and more particularly to a lithium microbattery, the invention is transposable to any microelectronic device 300, possibly sensitive to air (dioxygen and water vapour). For example it can be a capacitive stacking or an electrochrome component.

The invention is also transposable to a group of microelectronic devices by elementary structure.

As represented in FIG. 1, the microbattery 300 comprises cathode 301 and anode 302 current collectors, disposed on the substrate 200.

Current collectors 301, 302 are advantageously metallic. By way of illustration, they can be of titanium, gold, aluminium, platinum, or tungsten. They have, for example, a thickness of 300 nm.

Current collectors 301, 302 are electrically connected to electrical contacting elements 210 disposed on the substrate 200, and more particularly on the edge of the substrate (FIG. 2). The recontacting elements can thus be directly accessible from the side face of the substrate.

There are a so-called anode recontacting element and a so-called cathode recontacting element.

The recontacting elements can be on the first face 201 or second face 202 of the substrate 200. The largest dimension of the recontacting element 210 can be a few hundreds of micrometres.

According to another alternative embodiment, the current collectors 301, 302 form the recontacting elements 210.

Two active layers, one forming the negative electrode 303, and the other forming the positive electrode 304, are separated by an electrolyte layer 305. Each active layer 303, 304 is in contact with one of the current collectors 301, 302.

The positive electrode 304 (cathode) is of a material having good electronic and ionic conductivity (for example TiOS, TiS₂, LiTiOS, LiTiS₂, LiCoO₂, V₂O₅ . . . ). A cobalt oxide positive electrode will be preferably selected. This type of cathode is considered as one of the best performing layers for microbatteries and at the same time as the most stress-subjected layers during the manufacturing steps. Indeed, the mechanical stresses generated after forming the cathode layer (heat expansion coefficient between 10×10⁻⁶/° C. and 15×10⁻⁶/° C. and a Young's modulus between 100 and 500 GPa) can influence the behaviour of rigid substrates once they are thinned.

The electrolyte 305 is an electronic insulator with a large ionic conductivity (for example LiPON, LiPONB, LiSiCON . . . ).

The negative electrode 303 (anode) is a layer which can be metal lithium or lithiated material.

Optionally and according to configurations, the active layers can be protected by a primary encapsulation system consisting of one or more elementary barrier layers the main role of which is to guarantee integrity of microbattery devices during different phases of the method.

The microbattery will be made by techniques known to those skilled in the art.

Step 2: Manufacturing the Rigid Structured Support 400 for Manufacturing the Assembly Mould 500:

This step is independent of the step of manufacturing microbatteries (step 1). It can be made prior or subsequently to step 1.

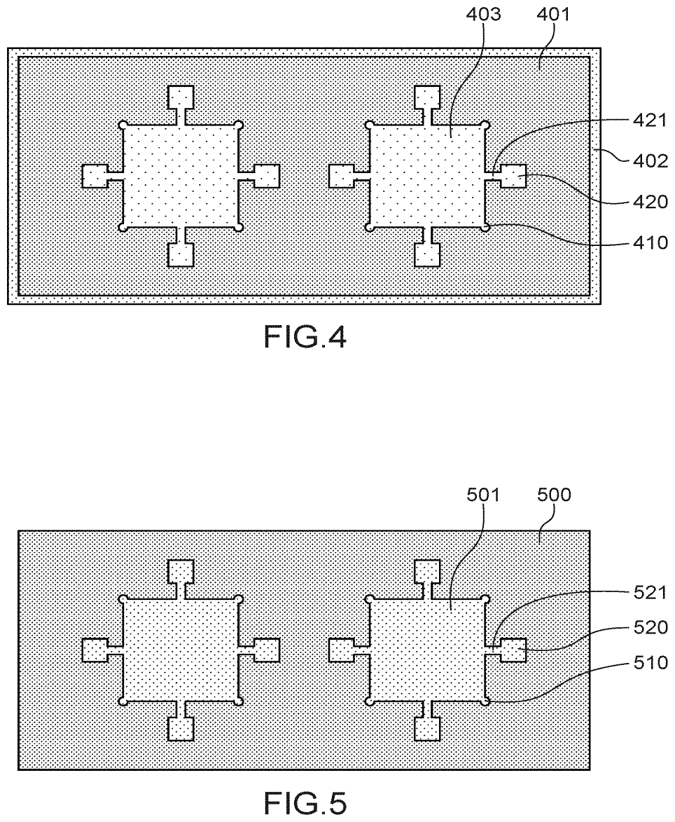

The structured support 400, represented in FIGS. 3 and 4, is of a rigid plastic material.

The support 400 is of a material the melting temperature of which is greater than that of the mould. In other words, the support material has to be compatible with methods for curing the polymeric material of the mould. For example, a material having a resistance to temperatures greater than 200° C. will be selected.

The material will be preferably selected from a metal, ceramic, polymer, dielectric material or one of their mixtures. Generally, any material or mixture of materials for creating compartmentalised zones can be used.

By way of illustration, it can be a material selected from PVC, PMMA, silicon, quartz, glass . . . .

Preferably, the support 400 is of polytetrafluoroethylene (PTFE) marketed under the Téflon® reference.

The support 400 has a planar part 401 covered with projecting parts 403 forming one or more zones protruding from the planar part 401. The support comprises a protruding edge 402 on the periphery. The protrusion value, defining in the following the depth of the mould, is set as a function of the number of elementary structures to be stacked. By way of example, a protrusion of 400 μm enables 5 elementary structures to be stacked.

The support 400 can be manufactured for example by mechanical machining, laser machining, physical machining, or chemical etching techniques.

According to another alternative, it can be thermoformed.

According to another alternative, the support 400 can be obtained by securing different elements 402, 403 to a planar support 401 so as to create relief zones. According to this embodiment, the planar base 401 of the support 400 and the relief elements 402, 403 can be of identical or different materials.

The support 400 can have a thickness of 3 mm to 10 mm, for example 5 mm.

According to a particularly advantageous embodiment represented in FIG. 4, complementary zones 410, 420, 421 can be brought to the design of the support. The complementary zones are especially solid zones in the support and will therefore be recessed zones in the mould. For example, the complementary zones can make it possible to define clearances, microcavities acting as micron size tanks (microtanks) connected to flowing channels for injecting a liquid element or viscous element such as an adhesive or for recovering the excess adhesive resulting from the assembling method.

A structuration and/or texturation of the support 400 for easily manufacturing the mould 400, in particular for flowing a polymer in the liquid state, will be selected.

Depending on the machining technique for the support 400, the inaccuracy in dimensions can be limited to a few microns.

Step 3: Manufacturing the Assembly Mould:

Manufacturing the assembly mould 500 is obtained by creating a so-called ‘negative’ replica of the support 400 (FIG. 5).

The mould 500 is preferably, of an elastomeric material. An organic polymer will be advantageously selected.

The method for manufacturing the assembly mould 500 preferably comprises the following steps of:
filling the rigid structured support 400 with a polymer in the liquid state,
solidifying the polymer whereby a polymer mould 500 is formed.

According to a particularly advantageous embodiment, the polymer in the liquid state is mixed with a crosslinking agent before being poured onto the structured support 400. The whole is then heated to form the mould 500 after thermal crosslinking. And then the whole is cooled to room temperature (typically from 20 to 25° C.).

The solidifying step (also called curing step) is for shaping a robust mould 500 of polymeric material containing compartments to accommodate unit components.

Alternatively, the solidifying step can be performed at room temperature, by selecting a waiting time sufficient to lead to solidifying the polymeric mould.

The mould is then released from the support.

A polymer fulfilling one or more of the following criteria will advantageously be selected: aversion towards adhesives, flexibility, temperature resistance preferably up to 150° C. and preferably up to 200° C.

The mould of polymeric material, once it is solidified and/or cross-linked is deformable (FIG. 6). By deformable material, it is meant a material able to undergo a non-permanent deformation from 10 to 1000% relative to its initial shape, preferentially from 50 to 200% relative to its initial shape. By non-permanent deformation, it is meant that, after deformation, it returns to its initial shape.

Advantageously, the polymer is a polysiloxane. For example, it has a viscosity lower than 20 Pa·S in the liquid state. Here, and in the following, viscosity values are given at 25° C. This material is flexible, deformable and hardly sensitive to variations in temperature. Elongation at break can exceed 100% or even reach values in the order of 1000% whereas the tensile strength can range from 0.1 MPa to 20 MPa.

By way of example, in the polysiloxane family, polydimethylsiloxane (known as PDMS and sometimes called dimethicole) which is an organomineral polymer (i.e. a structure containing carbon and silicon) could be chosen. Typically, PDMS in the liquid state is defined by a viscosity in the order of 5 Pa·S in the liquid state. After crosslinking, the PDMS mould has an elongation of 120%, a tensile strength in the order of 7.1 MPa and a thermal resistance up to 200° C. Advantageously, PDMS snugly fits the mask of the support without irreversibly bonding to the support.

For illustrative and not limiting purposes, the compartmentalised mould 400 is manufactured from the product marketed by Dow Corning under the reference Sylgard184.

The mould 400 can also be manufactured from the product marketed under the reference Ecoflex® by Smooth-On. These polymers have a very good elasticity (elongation before break which is close to a value of 1000% and a tensile strength lower than 2 MPa) and are very stable in a temperature range from −53° C. to 232° C. By way of example, the product marketed under the reference Ecoflex® 00-30 having a viscosity of 3 Pa·S can be mentioned. Shaping this elastomer will advantageously be followed by a first annealing operation for 4 hours at 23° C. and by a second annealing operation at 80° C. for 2 h. The mould obtained has an elongation in the order of 900% and a temperature resistance up to 232° C., which makes it possible to use insulating and conductive adhesives for assembling unit microbatteries the working temperature of which is greater than 200° C. and lower than 232° C.

According to an advantageous alternative, the mould 500 can also be of polyimide, for example of Kapton®.

The mould 500 comprises one or more main cavities 501 which can be of identical or different shapes and sizes depending on the dimensions and number of elementary structures to be stacked (FIG. 5). Dimensions of the main cavities 501 in the mould 500 advantageously correspond to the outer dimensions of the elementary structures to be assembled.

Each cavity 501 comprises a bottom and a side wall.

Advantageously, the main cavity(ies) 501 comprise(s) one or more clearances 510. These clearances 510 are for controlling the flow of adhesive, during assembly. This is particularly advantageous since forming an additional non-desired layer of adhesive outside the assembled components can reduce electrochemical performance of the device and/or create short-circuits. Moreover, clearances 510 also facilitate handling elementary structures.

Especially, in the case of a main cavity 501 the bottom of which is of a square shape, the presence of a clearance 510 at each of the four corners of the square-shaped main cavity 501 will facilitate positioning substrates 200 of elementary structures in the assembly mould 500. In particular, these holes 510 facilitate handling and positioning very thin (typically with a thickness lower than 100 μm) square-shaped substrates 200, which have brittleness at corners.

Step 4: Positioning Microbatteries 300 in the Assembly Mould 500:

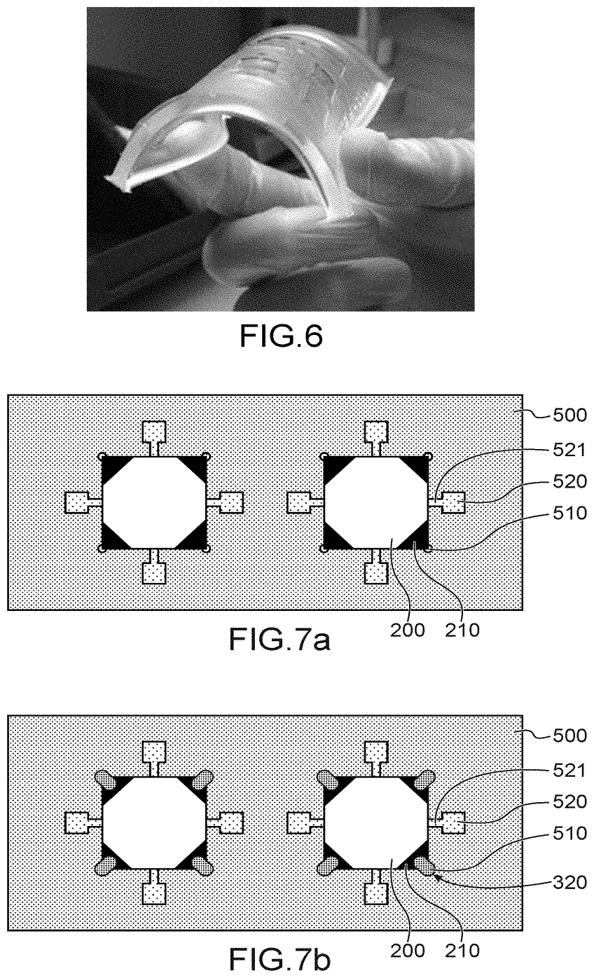

Aligning microbatteries 300 is facilitated by the total geometric match between the main cavity 501 of the mould and the substrates of elementary structures to be stacked (FIG. 7a). Typically, the accuracy of positioning of components 300 in the moulds can basically vary between 20 and 200 μm according to the machining technique (mechanical, laser, chemical) of the supports. Advantageously, it is lower than 50 μm.

This step enables a three-dimensional assembly of microbatteries 300 to be obtained. By three-dimensional assembly, it is meant a stacking of several unit microbatteries vertically superimposed.

In the following, a parallel connection of five identical square-shaped unit microbatteries will be described. It is quite possible to assemble another number of unit components having a square shape or another shape by adapting the geometric dimensions of the assembly mould.

For this, elementary structures comprising microbatteries are positioned into the main cavities 501 (FIGS. 7a and 7b), that is with the front face 201 of the substrate 200 facing upwards so as to have the back face 202 of the substrate 200 facing the bottom of the cavity and, advantageously, to make the electrical contacts 210 accessible.

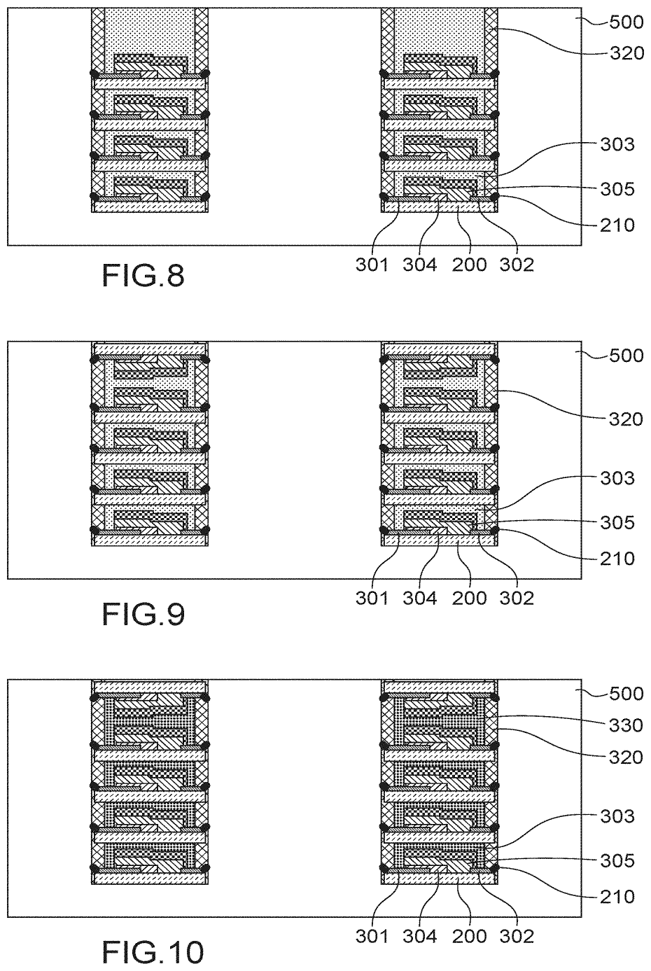

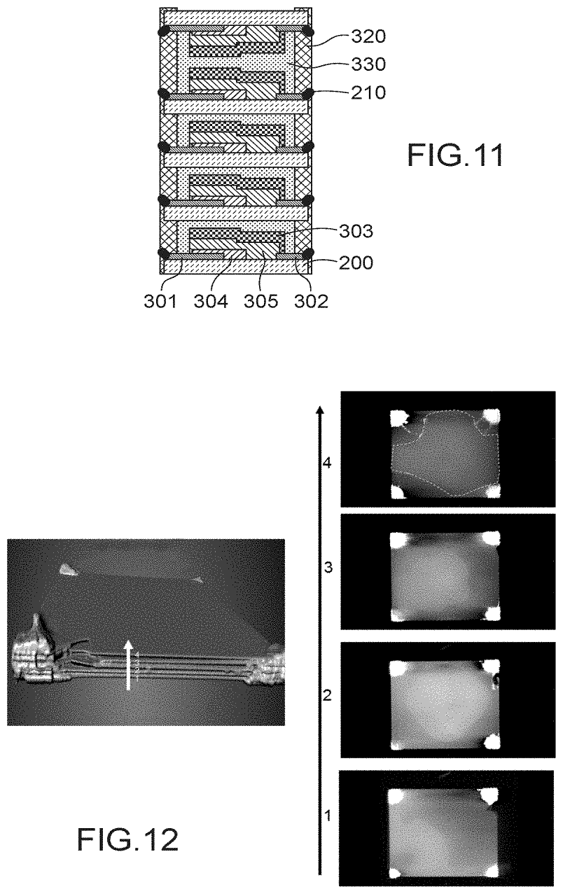

The different components are positioned in the main cavities 501 of the mould 500 and aligned with each other with a great accuracy (FIG. 8).

The unit components can be handled by hand or using a machine.

The unit components snugly fit the shape of the main cavities 501 by a simple geometric adjustment without resorting to complex and/or expensive techniques.

Preferentially, the fifth and last elementary structure is positioned in a so-called head to foot configuration, for having metallic collectors of the microbattery facing metallic collectors of the underlying elementary structure microbattery while fulfilling a parallel connection (FIG. 9). Such a configuration offers a complete encapsulation of the module of assembled microbatteries, by the presence of two substrates 200 which are water vapour- and oxidiser-proof on either side of the module of microbatteries. Thus, the different active layers are enclosed between the substrate of the first elementary structure and the substrate of the last elementary structure of the stack.

In an alternative implementation, microbatteries are electrically connected in series. These series connection can be performed by direct contact between the cathode collectors and anode collectors. Unlike the parallel connection, this embodiment enables an adjustment of the output voltage of the module of microbatteries.

According to the intended application, interconnecting several unit batteries is for modulating the electric power of the system obtained by increasing the output voltage (it is therefore a series connection) and/or discharge capacity (it is therefore a parallel connection). It is also possible to contemplate several configurations (series and parallel) within a same mould.

Step 5: Electrically Connecting Microbatteries:

In particular, during this assembly step, different anode contacts on the one side and cathode contacts on the other side are electrically linked in order to fulfil the disposition of a parallel connection mode.

The positioning/aligning operation of an elementary structure is followed by dispensing an electrically conductive adhesive or paste 320 at the electric contacts 210 (FIGS. 7b and 8).

Alternatively, it is possible to dispense the electrically conductive adhesive 320 before positioning the elementary structure.

Operations of positioning the elementary structures and dispensing the conductive adhesive 320 are repeated for four of the unit elements of the assembly (FIG. 8).

The adhesive can be deposited by screen printing for example.

Advantageously, the possible excess of conductive adhesive 320 is built up at the clearances 510 that facilitated handling of the substrates.

Curing the conductive adhesive 320 is made after positioning all the unit microbatteries. For example, it can be made by heating the assembly to a temperature of 80° C. to 180° C., preferably under air.

Optionally, a mechanical abutment is applied during thermal annealing of the conductive adhesive 320 for better spreading adhesive dots. Typically, the thickness of the conductive adhesive after the crosslinking step is 20 μm and the adhesive dot has a volume resistivity of 0.0004 Ω·cm.

Pads of conductive adhesive 320 thus formed at the four corners of microbatteries (FIG. 9) form zones for recontacting the module of microbatteries manufactured, enabling possible integration with external circuits. The shape of the adhesive pads can be regular (square, circular, elliptic, triangular) or random.

The adhesive is, for example, an epoxy adhesive containing electrically conductive particles, such as metallic particles. For example, it is the adhesive marketed under the reference Epo-Tek H20E by Epoxy Technology. Such adhesives have a volume resistivity lower than 4×10⁻⁴ ohm·cm.

The following references: Ablebond 84-1LMISR4, Hysol QMI516E marketed by Henkel or SMDLTLFP15T4 marketed by Chipquik can also be mentioned.

It is possible to use one-component or two-component type adhesives.

According to a particular embodiment, robustness and quality of electrical contacts are reinforced by an electrically conducting element. For example, it is possible to add metal rods at the electrical contacts. The metal rods are, for example, of copper. The metal rods can have a diameter of 50 μm. To form such a reinforcement, the rods can be embedded into the assembly mould 500 at the clearances 510 upstream of the assembly method. These metal rods are therefore integral with the mould. They are fastened in the electrically conductive adhesive as the unit microbatteries are positioned. The height of metal rods can be planed down at the end of the assembly method to register with the height of the module of microbatteries. Advantageously, the presence of these metal rods allows the use of standard techniques of integrating microelectronic devices by welding technologies.

Step 6: Mechanically Reinforcing the Module of Microbatteries:

During this step, the mechanical strength of the module of microbatteries is reinforced.

For this, an electrically insulating adhesive 330 is inserted into the inter-batteries space, preferably, from storage tanks 520 and through the channels 521 (FIG. 10).

Spacing between the different levels of the batteries is filled with insulating adhesives 330 thus making it possible to reinforce mechanical robustness of the module of batteries while ensuring physical separation.

An electrically insulating adhesive able to fill the empty spaces between each battery stage by capillarity will be selected. It can be an epoxy adhesive. By way of non-limiting example, bicomponent adhesives marketed by Epoxy Technology under the reference Epo-Tek 301-2 and 353ND can be mentioned. A mass mixture of both components of this reference according to the proportions 100 to 35 yields products with a viscosity of 0.3 Pa·S. Loctite Eccobond E1216M adhesive marketed by Henkel can also be used. Adhesives marketed by Henkel such as Ablebond 8387BM or Hysol QMI536 can also be selected.

Air annealing is then advantageously performed.

According to another alternative embodiment, a single step of curing by thermal annealing is performed to crosslink the electrically conductive adhesive and the electrically insulating adhesive simultaneously. By way of example, pairs of conductive adhesive/insulating adhesive marketed by Henkel will be selected: Ablebond 84-1LMISR4/Ablebond 8387BM (annealing for 1 hour at 175° C.) or Hysol QMI516E/Hysol QMI536 (1 h-annealing at 150° C.).

Generally, the curing conditions for electrically insulating and/or conductive adhesives can be monitored in a temperature range from 80° C. to 180° C. for amounts of time from one minute to one hour.

The volume of insulating adhesive stored in the tanks 520 is, advantageously, calibrated as a function of the quantity necessary to occupy the inter-batteries space left free by the stack of microbatteries (FIG. 10). For example, the volume of insulating adhesive estimated to ensure a homogeneous distribution of a 20 μm layer between 4 mm×4 mm sized batteries is in the order of 0.0013 mL.

The filling operation of vacant spaces between the unit batteries can be repeated as many times as necessary. The dedicated tanks 520 can be filled during the method for regenerating stock of insulating adhesive 330.

Beyond the their main roles (adhesion and electric conduction or insulation), adhesives aid in reinforcing sealing of the module obtained, and especially of lithium bearing-based microbatteries, towards atmosphere elements such as oxygen, nitrogen and water vapour.

The presence of electrically insulating adhesives advantageously enables sealing levels between 10⁻⁴ and 10⁻⁶ g·m⁻²·d⁻¹ for Water Vapour Transmission Rate (WVTR) and between 10⁻⁴ and 10⁻⁶ cm⁻³·m⁻²·d⁻¹ for Oxygen Transmission Rate (OTR) to be achieved.

Steps 5 and 6 may be performed consecutively according to the following steps: forming electrical contacts 320 and annealing, and then depositing the electrically insulating adhesive 330 and annealing.

According to an alternative implementation, it is possible to switch the order of steps 5 and 6: depositing the electrically insulating adhesive 330 and annealing, and then forming electrical contacts 320 and annealing.

Advantageously, separating the steps of applying the conductive adhesive 320 and insulating adhesive 330 aims at dispensing with possible chemical incompatibilities between these two adhesives. An insulating adhesive (also called “underfill”) will especially be chosen as a function of its capillarity.

According to another alternative embodiment, steps 5 and 6 are simultaneously carried out according to the following steps of: depositing the electrically insulating adhesive 330 and forming electrical contacts 320, and then annealing. In this case, a particular care has to be taken in choosing conductive and insulating adhesives in order to prevent any incompatibility phenomenon which can induce a degradation in electric conduction properties.

According to another alternative embodiment, the electric interconnection is made after depositing and annealing the electrically insulating layer 330 and once the device is out of the assembly mould. The electrically insulating adhesive secures the assembly and makes its handling easier during electric interconnection.

Annealing profiles can however be modified as a function of the nature of the mould, electrically conductive contacts and electrically insulating adhesive. Optionally, a mechanical force is applied upstream of the thermal treatment in order to homogenise spreading of insulating and conductive adhesives between the different stages constituting the module of microbatteries. This can lead to overflowing of a portion of adhesives under the effect of the mechanical pressure. Excess adhesives are advantageously discharged towards the microtank(s) 520 of the assembly mould 500 at the periphery of the main cavity 501 accommodating the microbatteries.

Step 7: Separating Assembled Microbatteries 300 of the Assembly Mould 500:

The mould release step is for insulating the module of microbatteries from the assembly mould.

This separating step is made possible by means of the aversion and deformability properties of the assembly mould 500. Mould releasing the module of microbatteries is preferably made by peeling. At the end of this step, the module of microbatteries has been separated from its assembly mould 500 (FIG. 1).

Mould release can be performed by hand or with specific tooling. For example, mould release can be performed by one or more repeated mechanical operations of contracting and relaxing moulds. The characteristic motions of the mould release method are possible by means of the elasticity and deformation properties of elastomeric materials in compression and tension. Using these properties therefore allows an easy release of the modules while keeping integrity of the moulds.

The assembly obtained at the end of the method can be used in a device having a simple encapsulation in thin layers (typically an encapsulation layer having a thickness lower than 10 μm) since the different adhesives thus enable a very high sealing level to be in fine ensured.

Advantageously, the moulds 500 are not deteriorated at the end of the method, and can be recycled for a new use, which reduces the cost of assembly operations.

### Illustrating and not Limiting Examples of an Embodiment

In this example, the microelectronic components 300 are microbatteries. The positive electrode is a 20 μm thick LiCoO₂ layer annealed at 600° C. for 10 h for a proper crystallisation of the LiCoO₂ material. The electrolyte 305 is 3 μm thick LiPON. The negative electrode 303 is a 50 nm silicon layer.

The cathode and anode current collectors are in the form of an isoceles triangle the sides of which of equal length are 200 μm.

The support 400 is of PTFE. It has a thickness of 5 mm. Recessed zones with a depth of 400 μm, relative to the base of the support, have been obtained by recessing material from the support 400, by milling. The solid zones 403 have a square shape with a surface area of 4.05 mm×4.05 mm.

The assembly mould 500 is of PDMS (Sylgard 184) with a viscosity of 3.5 Pa·s marketed by Dow Corning. The PDMS elastomer, in a liquid form, is poured on the support 400 in order to fill empty zones. Once the PDMS material is cured at a temperature of 150° C. for 10 minutes, it can be easily peeled from the support 400. The PDMS mould 500 corresponds to the topography replica of the support 400. The mould 500 thus manufactured (FIG. 6) is deformable without tensile and contractile failures up to 120% relative to its initial value. It also withstands temperatures close to 200° C. for about ten hours.

In this example embodiment, inaccuracy in positioning the unit elements is in the order of 50 μm. This inaccuracy is exclusively related to the technique of manufacturing the support 400 manufactured by mechanical milling. It is possible to improve this alignment accuracy by manufacturing assembly moulds 500 with a margin in the order of 10 μm by for example using chemical etching techniques or laser abrasion techniques.

The three-dimensional assembly of elementary structures, comprising lithium microbatteries, the outer geometric dimensions of which are 4 mm×4 mm is then performed in parallel.

By way of example, a 1 mL volume of Epo-Tek H20E adhesive (Epoxy Technology) is spread on the electrical contacts 210 by using a dispensing technique with calibrated syringes. This adhesive has a viscosity of 3.2 Pa·S. It is epoxy based and contains silver metal inclusions the average diameter of which is lower than 45 μm. It is a bicomponent adhesive the mixture mass ratio of which is 1:1.

After dispensing the adhesive, a thermal treatment is performed at a temperature of 150° C. for 10 minutes under air. A mechanical abutment (10 g mass) is applied during the thermal annealing of the conductive adhesive for a better spreading of adhesive dots.

The electrically insulating adhesive used to fill the inter-battery space is Epo-Tek 301-2 adhesive marketed by Epoxy Technology. A mass mixture of both components of this reference according to the proportions 100 to 35 yields products with a viscosity of 0.3 Pa·S. The thermal crosslinking profile of this reference needs a temperature of 80° C. for an amount of time of 3 hours under air.

After mould release, the assembly comprising 5 microbatteries is observed by tomography microscopy (FIG. 12). The different interfaces between the 5 unit microbatteries are clearly visible.

1. A reusable assembly mould, to manufacture a three-dimensional device comprising several microelectronic components vertically stacked, the assembly mould comprising a main cavity, formed by a bottom and a side wall,
the main cavity being configured to receive at least a first elementary structure and a second elementary structure which are stacked,
each elementary structure comprising a brittle substrate covered with a microelectronic component and with electrical contacts disposed on the edge of the substrate,
the assembly mould being of a deformable material able to undergo a non-permanent deformation from 10 to 1000% relative to its initial shape, preferentially from 50 to 200% relative to its initial shape,
the assembly mould further comprising a clearance positioned along the side wall of the main cavity to facilitate handling of the first elementary structure and/or second elementary structure and/or to inject an element along the main cavity.

2. The assembly mould according to claim 1, wherein it is of a polymeric material, preferably, polysiloxane.

3. The assembly mould according to claim 1, wherein the bottom of the main cavity has a square shape.

4. The assembly mould according to claim 1, wherein the assembly mould comprises an additional cavity, forming a tank, in fluid connection with the main cavity.

5. A method for manufacturing a three-dimensional device comprising several microelectronic components which are vertically stacked, the method comprising the following steps of:
a) providing a first elementary structure and a second elementary structure, each elementary structure comprising a brittle substrate having a first main face and a second main face, the first main face of the substrate being covered with a microelectronic component, and with electrical contacts, disposed on the edge of the substrate, and electrically connected to the microelectronic component,
b) providing an assembly mould such as defined in claim 1, comprising a main cavity, formed by a bottom and a side wall, and configured to receive at least two elementary structures, the assembly mould being of a deformable material able to undergo a non-permanent deformation from 10 to 1000% relative to its initial shape, preferentially from 50 to 200% relative to its initial shape,
c) disposing the first elementary structure into the main cavity of the assembly mould,
d) forming a layer of electrically insulating adhesive on the first elementary structure,
e) disposing the second elementary structure into the main cavity of the assembly mould,
f) electrically connecting the electrical contacts of the first elementary structure and the electrical contacts of the second elementary structure,
whereby a three-dimensional device comprising several microelectronic components which are vertically stacked is formed.

6. The method according to claim 5, wherein steps d), e) and f) are performed in the following order: e), d) and then f).

7. The method according to claim 5, wherein steps d), e) and f) are performed in the following order: e), f) and then d).

8. The method according to claim 5, wherein the assembly mould comprises an additional cavity, forming a tank, in fluid connection with the main cavity, and wherein the layer of electrically insulating adhesive is formed by injecting the electrically insulating adhesive between the elementary structures from the additional cavity.

9. The method according to claim 5, wherein the assembly mould comprises a clearance, positioned along the side wall of the main cavity, at the electrical contacts of the elementary structures and wherein step f) is performed by filling the clearance with an electrically conductive element whereby the electrical contacts of both elementary structures are connected.
